(19) United States
(12) Patent Application Publication
(10) Pub. No.: US 2009/0197202 A1
(43) Pub. Date: Aug. 6, 2009

(54) PHOTOSENSITIVE PLANOGRAPHIC PRINTING PLATE MATERIAL

(75) Inventor: Toshiyuki Matsumura, Kanagawa (JP)

Correspondence Address: LUCAS & MERCANTI, LLP, 475 PARK AVENUE SOUTH, 15TH FLOOR, NEW YORK, NY, 10016, US

(73) Assignee: KONICA MINOLTA MEDICAL & GRAPHIC, INC., Tokyo (JP)

(21) Appl. No.: 12/299,048

(22) PCT Filed: Apr. 25, 2007
(86) PCT No.: PCT/JP2007/058935

§ 371 Date: Oct. 30, 2008

(30) Foreign Application Priority Data
May 9, 2006 (JP) 2006130064

(51) Int. Cl. G03F 7/004

(52) U.S. Cl. 430/286.1

(57) ABSTRACT

Disclosed is a photosensitive surface printing plate material which is suitable for the exposure to a laser beam having a light emission wavelength ranging from 350 to 450 nm, is highly sensitive, and has excellent storage stability. The material has a substrate and a photosensitive layer provided on the substrate, wherein the photosensitive layer comprise a polymerization initiator (A), a polymerizable compound (B) having an ethylenic double bond, a sensitizing dye (C), and a polymeric binder (D). In the photosensitive layer, the polymerizable compound (B) comprises a product of the reaction among (a) a compound represented by the general formula (1), (b) a diisocyanate compound and (c) a (methacrylate compound having a hydroxyl group in the molecule. General formula (1): HO—(CH₂)ₙ—NH—CHR¹R² wherein R¹ and R² independently represent an alkyl group or an aralkyl group, provided that R¹ and R² may together form a ring; and n is an integer of 1 to 10.

### FIELD OF THE INVENTION

This invention is directed to a planographic printing plate employed for computer to plate system (referred as CTP hereafter), and, in particular, the planographic printing plate suitable for exposure with laser-light having wave length of 350-450 nm.

### BACKGROUND

CTP, in which digital data of an image is recorded directly on a planographic printing plate by laser light, has been developed and is realized to practically use in a preparation technique of printing plate for offset printing.

It is a common knowledge to employ a negative type photosensitive planographic printing plate material having polymerizing type photosensitive layer which contains a polymerizable compound, for example, a printing material as disclosed in JP A H01-105238 or H02-127404, in the printing field relatively high printing property is required. A printing material has also become known which is capable of image exposure with laser having wavelength of 390-430 nm having an improved safe-light property in view of easy handling the printing plate.

As high power and compact laser apparatus emitting blue violet laser having wave length of 390-430 nm can be available, a photosensitive planographic printing plate has been developed which is suitable for the laser wave length and is capable of handling under day light. (Reference is made to Patent Documents Nos. 1 and 2)

It is also known a printing plate comprising a biimidazole in a photosensitive layer and improving safe-light property against yellow light as disclosed in JP A 2001-194782. It is also known a high sensitive low sublimation photopolymerization composition, for example, a photopolymerizable composition comprising a hexarylbiimidazole compound having a substituent such as an alkyl group as disclosed in JP A 2004-137152.

A methacrylate compound, a tert-amine compound having a hydroxy group in its molecule, and a diisocyanate compound as a polymerizable compound is known as the polymerization compound used for the photosensitive layer of these printing plate materials. (Patent Document No. 3)

Problems are sometimes found that sensitivity is not sufficient or sensitivity change is large due to storage of the photosensitive planographic materials in these printing materials.

Patent Document No-1: JP A 2000-98605

Patent Document No. 2: JP A 2001-264978

Patent Document No. 3: Japanese Patent No. 2669849

### SUMMARY OF THE INVENTION

### Problems to Dissolve by this Invention

An object of this invention is to provide a photosensitive planographic printing plate which is suitable for exposure to laser light having emission wave length of 350-450 nm, and have high sensitivity and excellent storage stability.

### Technical Means to Dissolve the Problems

The problems described above are accomplished by the follows.

1. A photosensitive planographic printing plate material having a photosensitive layer comprising (A) a polymerization initiator, (B) a polymerizable compound having ethylenic double bond, (C) a sensitizing dye, and (D) a polymer binder, on a support,
wherein the photosensitive layer comprises a reaction product of (a) a compound represented by formula (1), (b) a diisocyanate compound, and (c) a methacrylate or acrylate compound having a hydroxy group in a molecule, as (B) a polymerizable compound having ethylenic double bond.

HO—(CH₂)ₙ—NH—CHR¹R² Formula (1)

In the formula, R¹ and R² independently represent an alkyl or aralkyl group, and R¹ and R² may form a ring by bonding. n is an integer of 1-10.
2. A photosensitive planographic printing plate material as described in 1, wherein the photosensitive layer comprises a hexarylbiimidazole compound as (A) a polymerization initiator.
3. A photosensitive planographic printing plate material as described in 1 or 2, wherein the photosensitive layer comprises a coumarin derivative or stilbene derivative as (C) a sensitizing dye.

### ADVANTAGE OF THE INVENTION

It becomes possible to provide a photosensitive planographic printing plate which is suitable for exposure to laser light having emission wave length of 350-450 nm, and have high sensitivity and excellent storage stability by this invention.

### BEST EMBODIMENT TO PRACTICE THE INVENTION

Though the best embodiment to practice this invention will be described, by which this invention is not restricted.

This invention is characterized in that a photosensitive planographic printing plate material having a photosensitive layer comprising (A) a polymerization initiator, (B) a polymerizable compound having ethylenic double bond, (C) a sensitizing dye, and (D) a polymer binder, on a support, wherein the photosensitive layer comprises a reaction product of (a) a compound represented by formula (1), described above (b) a diisocyanate compound, and (c) a methacrylate or acrylate compound having a hydroxy group in a molecule, as (B) a polymerizable compound having ethylenic double bond.

A photosensitive planographic printing plate material having high sensitivity and excellent storage stability is obtained by that, particularly, a photosensitive layer contains a reaction product of (a) a compound represented by formula (1), described above (b) a diisocyanate compound, and (c) a methacrylate or acrylate compound having a hydroxy group in a molecule

### (B) Polymerizable Compound Having Ethylenic Double Bond

The photosensitive layer according to this invention comprises a reaction product of (a) a compound represented by formula (1), described above (b) a diisocyanate compound, and (c) a methacrylate or acrylate compound having a hydroxy group in a molecule as the (B) a polymerizable compound having ethylenic double bond.

### (a) A Compound Represented by Formula (1)

In the formula (I) described above, R¹ and R² independently represents an alkyl or aralkyl group. R¹ and R² may form a ring by bonding. n is an integer of 1-10.

Examples of R¹ and R² are preferably a methyl, ethyl, propyl, butyl, pentyl and benzyl group. It is also preferred that R¹ and R² form a cyclohexyl or cyclopentyl ring by bonding.

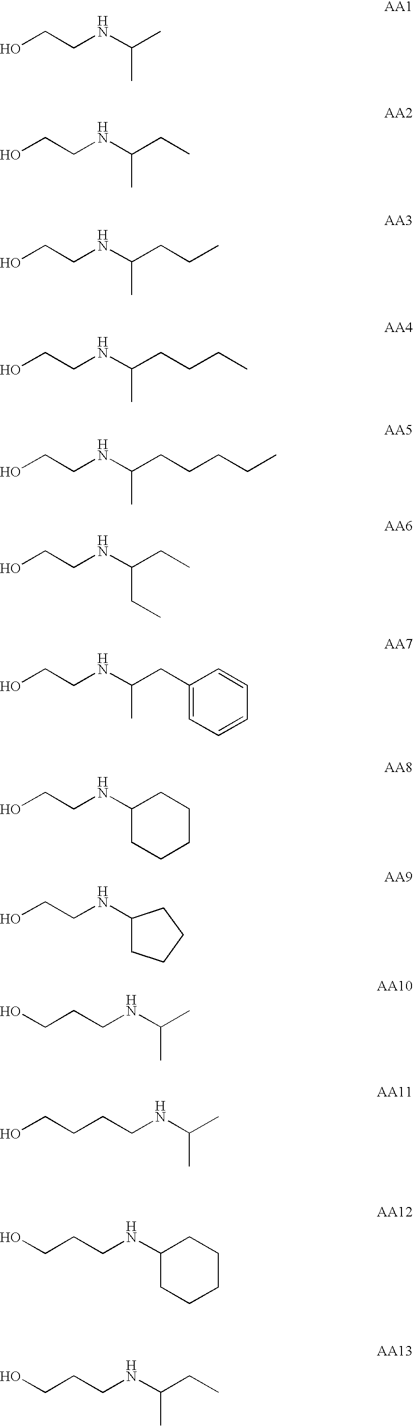

The particularly preferable compounds represented by formula (1) include AA1, AA2, AA6, AA7 and AAS.

### (b) Diisocyanate Compound

Dilsocyanate compound according to this invention includes diisocyanate, and there is no particular limitation to the diisocyanate compound and preferably employed are diisocyanates described below.

A particularly preferable diisocyanate compound includes xylene diisocyanate, tetramethyl xylene diisocyanate, hexamethylene diisocyanate, isophorone diisocyanate.

Practical examples of the diisocyanate compound according to this invention are listed.

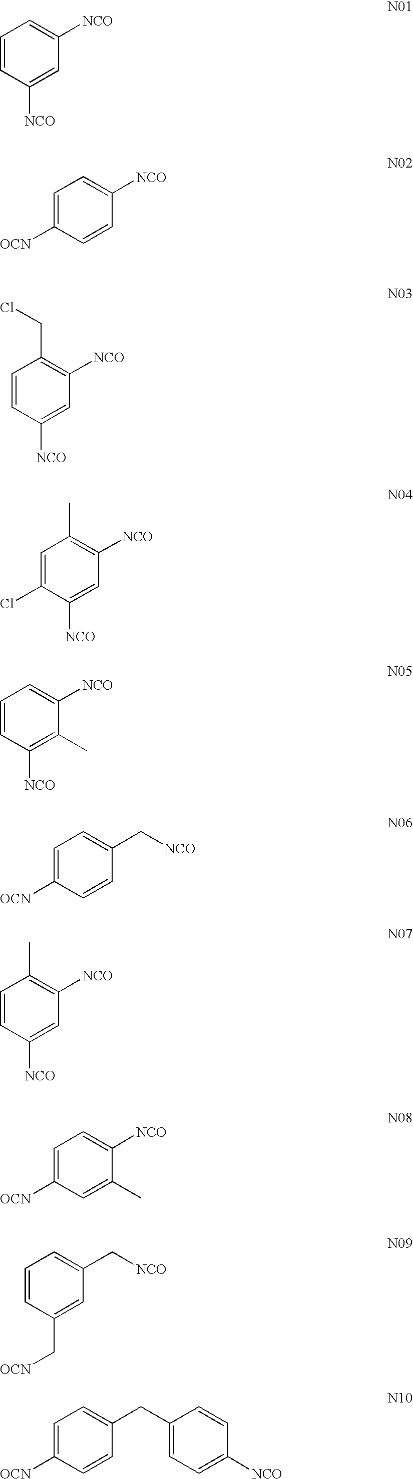

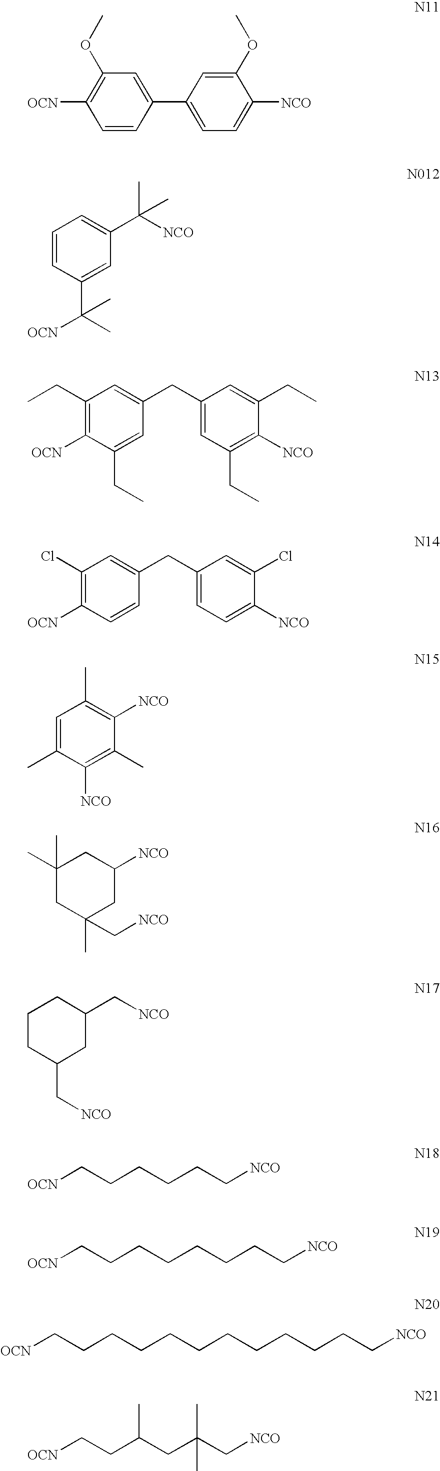

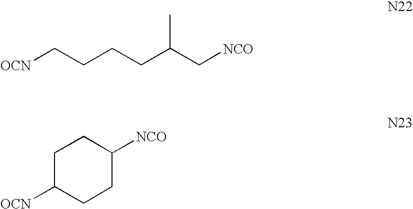

### (c) Methacrylate or Acrylate Compound Having a Hydroxy Group in a Molecule

Examples of methacrylate or acrylate compound having a hydroxy group in a molecule include 2-hydroxyethyl methacrylate, 2-hydroxypropyl methacrylate, 2-hydroxyethyl acrylate, 2-hydroxypropyl acrylate, 4-hydroxybutyl acrylate, 2-hydroxy-3-methacryloyloxy propyl methacrylate, and 2-hydroxy-3-acryloyloxypropylmethacrylate.

It is preferable to select a ratio of the total mol number of hydroxy group and amino group to total react the total mol number of diisocyanate group in the compound is from 1.2:1.0 to 1.0:1.2 in the reaction of the compounds described above.

It is preferable to combine the compounds so that molar ratio of (aminoalcohol compound represented by formula (1)): (diisocyanate compound):(methacrylate compound having hydroxy group within molecule) is (1±0.2):(2±0.4):(2±0.4) practically.

The reaction of these compounds can be performed in a condition of general urethane forming reaction, in which reaction is made in the presence of catalyser such as tin complex in a solvent having no functional group such as an amino, hydroxy or carboxy group.

A small amount of a hindered phenol type antioxidant and polymerization inhibitor such methoxyphenols may be added to the solution after reaction so as to improve the storage ability.

A content of the reaction product synthesized as above according to this invention in the photosensitive layer is preferably 3-70%, more preferably 5-50% by mass.

A common radically polymerizable compound, so called photo polymerizable monomer or photo polymerizable oligomer may be employed in combination.

These compounds are not specifically limited but preferred compounds are mono-functional acrylic acid esters such as 2-ethylhexyl acrylate, 2-hydroxypropyl acrylate, glycerol acrylate, tetrahydrofurfuryl acrylate, phenoxyethyl acrylate, nonylphenoxyethyl acrylate, tetrahydrofurfuryloxyethyl acrylate, tetrahydrofurfuryloxyhexanolide acrylate, acrylate of ε-caprolactone of 1,3-dioxane alcohol and 1,3-dioxolan acrylate; methacrylic acid, itaconic acid, crotonic acid and maleic acid esters obtained by replacing the foregoing acrylates by methacrylate, itaconate, crotonate, or maleate, e.g., ethylene glycol diacrylate, triethylene glycol diacrylate, pentaerythritol diacrylate, hydroinone diacrylate, resorcin diacrylater hexanediol diacrylate, neo-pentyl glycol diacrylate, tripropylene glycol diacrylate, diacrylate of hydroxypivalic acid neo-pentylglycol, diacrylate of neopentylglycol adipate, diacrylate of ε-caprolactone of hydroxypivalic acid neo-pentyl glycol, 2-(2-hydroxy-1,1-dimethylethyl)-5-hydroxymethyl-5-ethyl-1,3-dioxane diacrylate, tricyclodecanedimethylol acrylate, ε-caprolactone of tricyclodecanedimethylol acrylate and diacrylate of diglycidyl ether of 1,6-hexanediol; methacrylic acid, itaconic acid, crotonic acid and maleic acid esters obtained by replacing the foregoing acrylates by methacrylate, itaconate, crotonate, or maleate, e.g., polyfunctional acrylic acid ester acid such as trimethylolpropane triacrylate, ditrimethylolpropane tetraacrylate, trimethylolethane triacrylate, pentaerythritol triacrylate, pentaerythritol tetraacrylate, dipentaerythritol tetraacrylatei dipentaerythritol pentaacrylate, dipentaerythritol hexaacrylate, ε-caprolactone adduct of dipentaerythritol hexaacrylate, pyrogallol triacrylate, propionic acid/dipentaerythritol triacrylate, propionic acid/dipentaerythritol tetraacrylate and hydroxypivalylaldehyde-modified dimethylolpropane triacrylate and esters of methacrylic acid, itaconic acid crotonic acid or maleic acid, obtained by replacing these acrylates by methacrylate, itaconate, crotonate or maleate.

Similarly to the foregoing, prepolymers are also usable. As a prepolymer are cited compounds as described below but a prepolymer in which acrylic acid or methacrylic acid is introduced into an oligomer having an appropriate molecular weight to provide photopolymerizability, is also suitably usable. These prepolymers may be used alone or in combination. Alternatively, monomers described above and oligomers may be used in a mixture.

Examples of prepolymers include polyester acrylates obtained by introducing (meth)acrylic acid into a polyester obtained by the combination of a polybasic acid and a polyhydric alcohol, for example, polybasic acids such as adipic acid, trimellitic acid, maleic acid, phthalic acid, terephthalic acid, HIMIC ACID, malonic acid, succinic acid, glutaric acid, itaconic acid, pyromellitic acid, fumaric acid, pimelic acid, sebacic acid, dodecanoic acid or tetrahydrophthalic acid and polyhydric alcohols such as ethylene glycol, propylene glycol, diethylene glycol, propylene oxide, 1,4-butanediol, triethylene glycol, tetraethylene glycol, polyethylene glycol, glycerin, trimethylolpropane, pentaerythritol, sorbitol, or 1,6-hexanediol, 1,2,6-hexanetriol; epoxyacrylate in which (meta)acrylic acid is introduced into an epoxy resin, such as bisphenol A-epichlorohydrin-(meta)acrylic acid and phenol novolak-epichlorohydrin-(meta)acrylic acid; urethane acrylate in which (meta)acrylic acid is introduced into urethane resin, such as ethylene glycol-adipic acid-tolylenediisocyanate-2-2-hydroxyethyl acrylate, polyethylene glycol-tolylenediisocyanate-2-hydroxyethyl acrylate, hydroxyethylphthalyl methacrylate-xylenediisocyanate, 1,2-polybutadiene glycol-tolylene diisocyanate-2-hydroxyethyl acrylate, or trimethylolpropane-propylene glycol-tolylene diisocyanate-2-hydroxyethyl acrylate; silicone resin acrylates such as polysiloxane acrylate or polysiloxane-diisocyanate-2-hydroxyethyl acrylate; alkyd-modified acrylates in which (metaflacryloyl group is introduced into an oil-modified alkyd resin; and spiran resin acrylates.

The photosensitive layer according to this invention can contain a monomer such as phosphazene monomer, triethylene glycol, isocyanuric acid ethylene oxide (EO)-modified diacrylate, isocyanuric acid ethylene oxide (EO)-modified triacrylate, trimethylolpropane acrylic acid benzoic acid ester, alkylene glycol type acrylic acid modification, and urethane-modified acrylate, and addition-polymerizable oligomer or prepolymers containing a constituting unit formed of the foregoing monomers.

A phosphoric acid ester compound containing at least one (meta)acryloyl group is listed as an ethylenic monomer usable in combination. This compound is one in which at least a part of hydroxyl groups of phosphoric acid is esterified and is not specifically limited so long as a (meta)acryloyl group is contained.

There are also usable compounds described in JP-A S58-212994, S31-6649, S62-46688, S62-48589, S62-173295, S62-187092, S63-67189 and H01244891. Further, compounds described in “Chemical Goods of 11290” Kagakukogyo Nippo-sha, pages 286-294, and “UV/EB Curing Handbook (Raw Material Rev.)” Kobunshi Kankokai pages 11-65 are also suitably usable. Of these, a compound containing at least two acryl groups or methacryl groups within the molecule is preferred in the invention, and one having a molecular weight of not more than 10,000, more preferably, not more than 5,000, is preferred.

Acrylate or alkyl acrylate compounds described in H01-105238 and H02-127404 may be employed.

The content of a compound containing a polymerizable ethylenic double bond (B) containing the reaction product according to this invention in the photosensitive layer is preferably 5% to 70% by mass, and more preferably 10% to 60% by mass in terms of photosensitive layer.

### (A) Polymerization Initiator

The polymerization initiator according to this invention is a compound which can initiate polymerization of polymerizable ethylenic double bond compound via image exposure. Preferably employable polymerization initiator includes a titanocene compound, a monoalkyltriarylborate compound, iron arene complex compound, a polyhalogen compound and a biimidazole compound, and biimidazole compound is particularly preferable which demonstrate the advantage of the invention markedly among them.

The biimidazole compound is a derivative of biimidazole, and includes compound disclosed in JP A 2003-295426.

As the bimidazole compound, hexarylbiimidazole (HABI, a dimer of triarylimidazole) compound can be preferably used in this invention.

Manufacturing process of HABIs is disclosed in DE 1,470,154, and their use in the photopolymerizable composition is disclosed in EP 24,629, EP 107,792, U.S. Pat. No. 4,410,621, EP 215,453, and DE 3,211,312.

Preferable examples include 2,4,5,2′,4′,5′-hexaphenylbiimidazole, 2,2′-bis(2-chlorophenyl)-4,5,4′,5′-tetraphenylbiimidazole, 2,2′-bis(2-bromophenyl)-4,5,4′,5′-tetraphenylbiimidazole, 2,2′-bis(2,4-dichlorophenyl)-4,5,4′,57-tetraphenylbiimidazole, 2,2′-bis(2-chlorophenyl)-4,5,4′,5′-tetrakis(3-methoxyphenyl)biimidazole, 2,2′-bis(2-chlorophenyl)-4,5,4′,5′-tetrakis(3,4,5-trimethoxyphenyl)biimidazole, 2,5,2′,5′-tetrakis(2-chlorophenyl)-4,4′-bis(3,4-dimethoxyphenyl)biimidazole, 2,2′-bis(2,6-dichlorophenyl)-4,5,4′,5′-tetraphenylbiimidazole, 2,2′-bis(2-nitrophenyl)-4,5,4′,5′-tetraphenylbiimidazole, 2,2′-di-o-tolyl-4,5,4′,5′-tetraphenylbiimidazole, 2,2′-bis(2-ethoxyphenyl)-4,5,4′,5′-tetraphenylbiimidazole, and 2,2′-bis(2,6-diphenyl)-4,5,4′,5′-tetraphenylbiimidazole.

As titanocene compounds are cited those described in JP-A S63-41483 and H02-291, and specific examples thereof include bis(cyclopentadienyl)-Ti-dichloride, bis(cyclopentadienyl)-Ti-bis-phenyl, bis(cyclopentadienyl)-Ti-bis-2,3,4,5,6-pentafluorophenyl, bis(cyclopentadienyl)-Ti-bis-2,3,5,6-tetrafluorophenyl, bis(cyclopentadienyl)-Ti-bis-2,4,6-trifluorophenyl, bis(cyclopentadienyl)-Ti-bis-2,6-difluorophenyl, bis(cyclopentadienyl)-Ti-bis-2,4-difluorophenyl, bis(methylcyclopentadienyl)-Ti-bis-2,3,4,5,6-pentafluorophenyl, bis(methylcyclopentadienyl)-Ti-bis-2,3,5,6-tetrafluorophenyl, bis(methylcyclopentadienyl)-Ti-bis-2,6-difluorophenyl (IRUGACURE 727L, Ciba Specialty Chemicals Co.), bis(cyclopentadienyl) bis(2,6-difluoro-3-(pyry-1-yl)phenyl)titanium (TRUGACURE 784, Ciba Specialty Chemicals Co.), bis(cyclopentadienyl)-bis(2,4,6-trifluoro-3-(pyry-1-yl)phenyl)titaniumbis(cyclopentadienyl)-bis(2,4,6-trifluoro-3-(2-5-dimethylpyry-1-yl)phenyl)titanium.

As monoalkyltriarylborate compounds are cited those described in JP-A S62-150242 and S62-143044, and specific examples thereof include tetra-n-butylammonium n-butyl-trinaphthalene-1-yl-borate, tetra-n-butylammonium n-butyl-triphenyl-borate₁ tetra-n-butylammonium n-butyl-tri-(4-tert-butylphenyl)-borate, tetra-n-butylammonium n-hexyl-tri-(3-chloro-4-methylphenyl)-borate and tetra-n-butylammonium n-hexyl-tri-(3-fluorophenyl)-borate.

As iron arene complex compounds are cited those described in JP-A S59-219307, and specific examples thereof include η-benzene-(η-cyclopentadienyl)iron-hexafluorophosphate η-cumene-(η-cyclopentadienyl)iron-hexafluorophosphate, η-fluorene-(η-cyclopentadienyl)iron-hexafluorophosphate, η-naphthalene-(η-cyclopentadienyl)iron-hexafluorophosphate, η-xylene-(η-cyclopentadienyl)iron-hexafluorophosphate and η-benzene-(η-cyclopentadienyl)iron-tetrafluoroborate.

A polyhalogen compound is a compound containing a trihalogenomethyl group, dihalogenomethyl group or a dihalogenomethylene group. Preferable examples are halogenated compounds represented by the following Formula (B) and oxadiazole compound substituted with the above-described halogenated groups.

The polyhalogen compounds represented by the following Formula (C) is used particularly preferably among them.

R¹—CY₂— Formula (B)

(C=¹ represents a hydrogen atom, a halogen atom, an alkyl group, an aryl group, an acyl group, an alkylsulfonyl group, an arylsulfonyl group, an iminosulfonyl group or a cyano group; R² represents a monovalent substituent, provided that R¹ and R² may combine with each other to form a ring; and Y represents a halogen atom.

CY₃—(C═O)—X—R³ Formula (C)

wherein R³ represents a monovalent substituent; X represents —O— or —NR⁴—, in which R⁴ represents a hydrogen atom or an alkyl group, provided that R³ and R⁴ may combine with each other to form a ring; and Y represents a halogen atom. Specifically, a compound containing a polyhalogen acetyl amide group is preferably used.

Other preferred examples are compounds having an oxadiazole ring substituted with a polyhalogen methyl group. Further, oxadiazole compounds disclosed in JP-A H05-34904, and H08-240909 are also preferably used.

Other polymerization initiators which may be used together are, carbonyl compound, organic sulfur compound, peroxide, redox compound, azo compound, diazo compound, halide compound and photoreductive dye, which are listed in J. Kosar, “Photosensitive Systems” Chapter 5. More specific compounds are disclosed in BP 1459563.

The following may be used as a polymerization initiator in combination.

Benzoin derivatives, such as benzoin methyl ether, benzoin-1-propyl ether, α,α-dimethoxy-α-phenyl acetophenone; benzophenone derivatives, such as benzophenone, 2,4-dichloro benzophenone, methyl-o-benzoylbenzoate, 4,4′-bis(dimethylamino)benzophenone; thioxanthone derivatives such as 2-chlorothioxanthone, 2-1-propylthioxanthone; anthraquinone derivatives, such as 2-chloroanthraguinone and 2-methyl anthraquinone; acridone derivatives such as N-methylacridone and N-butylacridone; α,α-diethoxyacetophenone, benzyl, fluorenone, xanthone, and uranyl compound; triazine derivatives described in Examined Japanese Patent Application Publication (JP-B) S59-1281 and S61-9621; JP-A S60-60104; organic peroxides described in JP-A S59-1504 and S61-243807; diazonium compounds described in JP-B S43-23684, S44-6413, S44-6413, 47-1604 and U.S. 3,567,453; organic azide compounds described in U.S. Pat. Nos. 2,848,328, 2,852,379, and 2,940,853; o-quinone diazides described in JP-B S36-22062b, S37-13109, S38-18015 and S45-9610; various onium compounds described in JP-B S55-39162, JP-A S59-14023 and “Macromolecules” volume 10, page 1307 (1977); azo compounds described in JP-A S59-142205; metal arene complexes described in JP-A H01-54440, EP 109,851 and 126,712, and J. Imag. Sci., volume 30 volume, page 174 (1986); (oxo)sulfonium organic boron complexes described in JP-Application H04-56831 and H04-B9535; transition metal complexes containing transition metals such as ruthenium described in “Coordination chemistry review” volume 84, pages 85-277 (1988), and JP-A H02-182701; 2,4,5-triarylimidazole dimer described in JP-A H03-209477; carbon tetrabromide; and halogenated organic compounds described in JP-A S59-107344.

Content of the polymerization initiator (total amount of the polymerization initiator) used in this invention is preferably 0.1-20% by mass, and more preferably 0.5-15% by mass based on the polymerizable ethylenic compound having unsaturated bond.

### C) Sensitizing Dye

The sensitizing dye according to this invention is a dye capable of sensitize the polymerization initiator, and preferably has a maximum absorption at wave length of 350-450 nm.

Sensitizing dyes include cyanines, merocyanines, porphyrins, spiro compounds, ferrocenes, fluorenes, fulgides, imidazoles, perylenes, phenazines, phenothiazines, acridines, azo compounds, diphenylmethanes, triphenylmethanes, triphenylamines, quinacridones, indigos, styryls, pyrylium compounds, pyrromethene compounds, pyrazolotriazole compounds, benzothiazole compounds, barbituric acid derivatives, thiobarbituric acid derivatives, ketoalcohol borate complex, cumarine derivatives, and stilbene derivatives.

A coumarin derivative and a stilbene derivative among them are preferably employed in this invention.

The coumalin derivative represented by the following formula (D) is preferably employed.

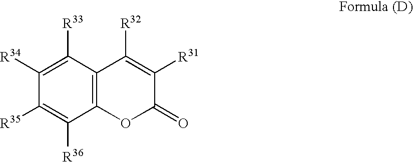

In the above formula R³¹ to R³⁶ is each a substituent. Examples of a substituent include an alkyl group (e.g., methyl, ethyl, propyl, isopropyl, tert-butyl, pentyl, hexyl, octyl, dodecyl, tridecyl, tetradecyl, pentadecyl), a cycloalkyl group (e.g., cyclopentyl, cyclohexyl), an alkenyl group (e.g., vinyl, allyl), an alkynyl group (e.g., ethynyl, propargyl), an aryl group (e.g., phenyl, naphthyl), a heteroaryl group (e.g., furyl, thienyl, pyridyl, pyridazyl, pyrimidyl, pyrazyl, triazyl, imidazolyl, pyrazolyl, thiazolyl, benzimidazolyl, benzoxazolyl, cuinazolyl, phthalazyl), a heterocyclic group (e.g., pyrrolidyl, imidazolidyl, morpholyl, oxazolidyl), an alkoxy group (e.g., methoxy, ethoxy, propyloxy, pentyloxy, hexyloxy, octyloxy, dodecyloxy), a cycloalkoxy group (e.g. cyclopentyloxy, cyclohexyloxy), an aryloxy group (e.g., phenoxy, naphthyloxy), an alkylthio group (e.g., methylthio, ethylthio, propylthio, pentylthio, hexylthio, octylthio, dodecylthio), a cycloalkylthio group (e.g., cyclopentylthio, cyclohexylthio), an arylthio group (e.g., phenylthio, naphthylthio), an alkoxycarbonyl group (e.g., methyloxycarbonyl, ethyloxycarbonyl, butyloxycarbonyl, octyloxycarbonyl, dodecyloxycarbonyl), an aryloxycarbonyl group (e.g., phenyloxycarbonyl, naphthyloxycarbonyl), a sulfamoyl group (e.g., aminosulfonyl, methylaminosulfonyl, dimethylaminosulfonyl, butylaminosulfonyl, hexylaminosulfonyl, cyclohexylaminosulfonyl, octylaminosulfonyl, dodecylaminosulfonyl, phenylaminosulfonyl, naphthylaminosulfonyl, 2-pyridylaminosulfonyl), an acyl group (e.g., acetyl, ethylcarbonyl, propylcarbonyl, pentylcarbonyl, cyclohexylcarbonyl, octylcarbonyl, 2-ethylhexylcarbonyl, dodecylcarbonyl, phenylcarbonyl, naphthylcarbonyl, pyridylcarbonyl), an acyloxy group (e.g., acetyloxy, ethylcarbonyloxy, butylcarbonyloxy, octylcarbonyloxy, dodecylcarbonyloxy, phenylcarbonyloxy), an amido group (e.g., methylcarbonylamino, ethylcarbonylamino, dimethylaminocarbonyl, propylcarbonylamino, pentylcarbonylamino, cyclohexylcarbonylamino, 2-ethylhexylcarbonylamino, octylcarbonylamino, dodecylcarbonylamino, phenylcarbonylamino, naphthylcarbonylamino), a carbamoyl group (e.g., aminocarbonyl, methylaminocarbonyl, dimethylaminocarbonyl, propylaminocarbonyl, pentylaminocarbonyl, cyclohexylaminocarbonyl, octylaminocarbonyl, 2-ethylhexylaminocarbonyl, dodecylaminocarbonyl, phenylaminocarbonyl, naphthylaminocarbonyl, 2-pyridylaminocarbonyl), an ureido group (e.g., methylureido, ethylureido, pentylureido, cyclohexylureido, octylureido, dodecylureido, phenylureido, naphthylureido, 2-pyridylureido), a sulfinyl group (e.g., methylsulfinyl, ethylsulfinyl, butylsulfinyl, cyclohexylsulfinyl, 2-ethylhexylsulfinyl, dodecylsulfinyl, phenylsulfinyl, naphthylsulfinyl, 2-pyridylsulfinyl), an alkylsulfonyl group (e.g., methylsulfonyl, ethylsulfonyl, butylsulfonyl, cyclohexylsulfonyl, 2-ethylhexylsulfonyl, dodecylsulfinyl), an arylsulfonyl group (e.g., phenylsulfonyl, naphthylsulfonyl, 2-pyridylsulfonyl), an amino group (e.g., amino, ethylamino, dimethylamino, butylamino, cyclopentylamino, 2-ethylhexylamino, dodecylamino, anilino, naphthylamino, 2-pyridylamino), a halogen atom (e.g., fluorine, chlorine, bromine, iodine), a cyano group, a nitro group, and a hydroxy group. These substituents may be further substituted by substituents described above. A plurality of these substituents may combine with each other to form a ring.

Of these is specifically preferred a coumalin containing, as R³⁵, an amino group, an alkylamino group, a dialkylamino group, an arylamino group, a diarylamino group or an alkylarylamino group. In that case, a coumalin in which an alkyl group substituted for an amino group combines with a substituent of R³⁴ or R³⁶ is also preferred.

More preferably, one of R³¹ and R³² or both of them are an alkyl group (e.g., methyl, ethyl, propyl, isopropyl, tert-butyl, pentyl, hexyl, octyl, dodecyl, tridecyl, tetradecyl, pentadecyl), a cycloalkyl group (e.g., cyclopentyl, cyclohexyl), an alkenyl group (e.g., vinyl, allyl), an aryl group (e.g., phenyl, naphthyl), a heteroaryl group (e.g., furyl, thienyl, pyridyl, pyridazyl, pyrimidyl, pyrazyl, triazyl, imidazolyl, pyrazolyl, thiazolyl, benzimidazolyl, benzoxazolyl, qulinazolyl, phthalazyl), a heterocyclic group (e.g., pyrrolidyl, imidazolidyl, morpholyl, oxazolidyl), an alkoxycarbonyl group (e.g., methyloxycarbonyl, ethyloxycarbonyl, butyloxycarbonyl, octyloxycarbonyl, dodecyloxycarbonyl), an aryloxycarbonyl group (e.g., phenyloxycarbonyl, naphthyloxycarbonyl), an acyl group (e.g., acetyl, ethylcarbonyl, propylcarbonyl, pentylcarbonyl, cyclohexylcarbonyl, octylcarbonyl, 2-ethylhexylcarbonyl, dodecylcarbonyl, phenylcarbonyl, naphthylcarbonyl, pyridylcarbonyl), an acyloxy group (e.g., acetyloxy, ethylcarbonyloxy, butylcarbonyloxy, octylcarbonyloxy, dodecylcarbonyloxy, phenylcarbonyloxy), a carbamoyl group (e.g., aminocarbonyl, methylaminocarbonyl, dimethylaminocarbonyl, propylaminocarbonyl, pentylaminocarbonyl, cyclohexylaminocarbonyl, octylaminocarbonyl, 2-ethylhexylaminocarbonyl, dodecylaminocarbonyl, phenylaminocarbonyl, naphthylaminocarbonyl, 2-pyridylaminocarbonyl), a sulfinyl group (e.g., methylsulfinyl, ethylsulfinyl, butylsulfinyl, cyclahexylsulfinyl, 2-ethylhexylsulfinyl, dodecylsulfinyl, phenylsulfinyl, naphthylsulfinyl, 2-pyridylsulfinyl), an alkylsulfonyl group (e.g., methylsulfonyl, ethylsulfonyl, butylsulfonyl, cyclohexylsulfonyl, 2-ethylhexylsulfonyl, dodecylsulfinyl), an arylsulfonyl group (e.g., phenylsulfonyl, naphthylsulfonyl, 2-pyridylsulfonyl), a halogen atom (e.g., fluorine, chlorine, bromine), a cyano group, a nitro group or a halogenated alkyl group (e.g., trifluoromethyl, tribromomethyl, trichloromethyl).

Specific examples of a preferred coumalin dye are shown below but are not limited to these.

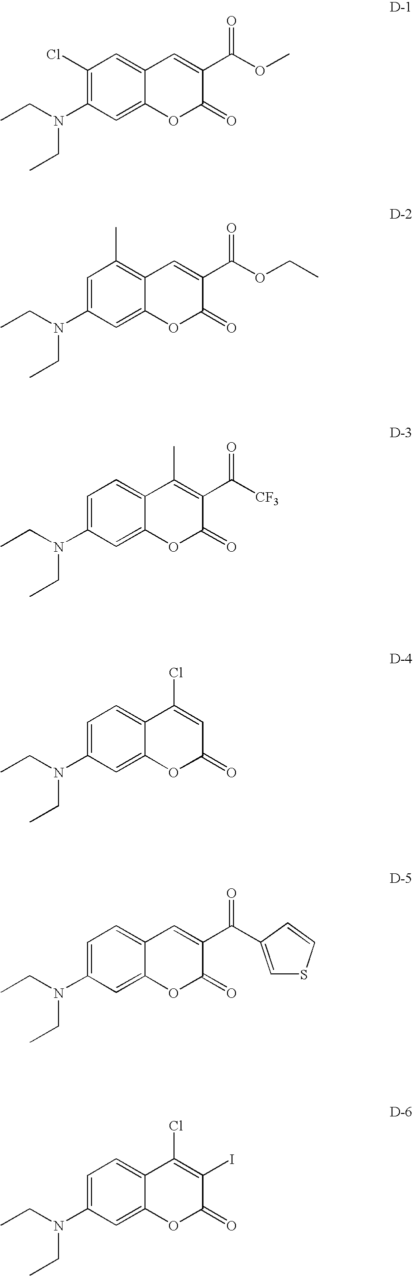

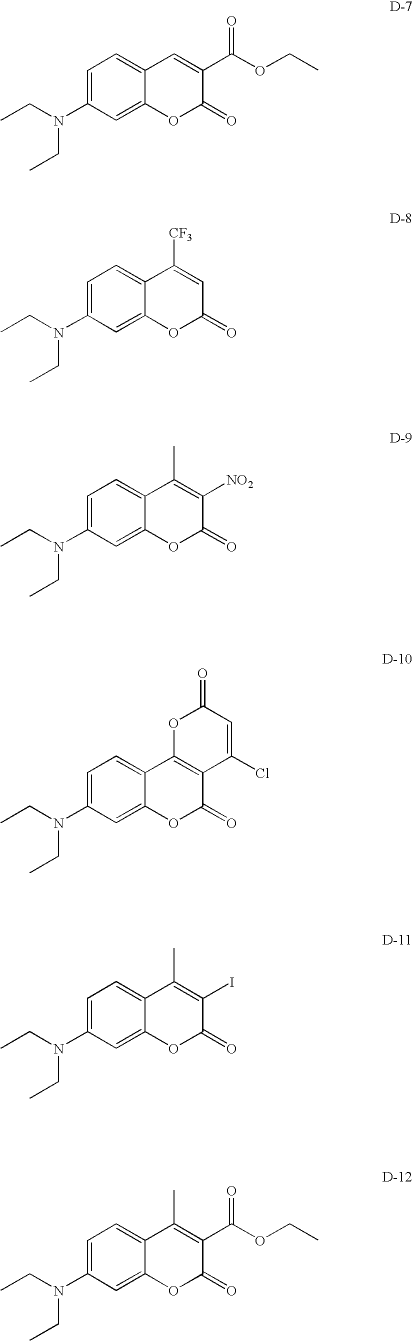

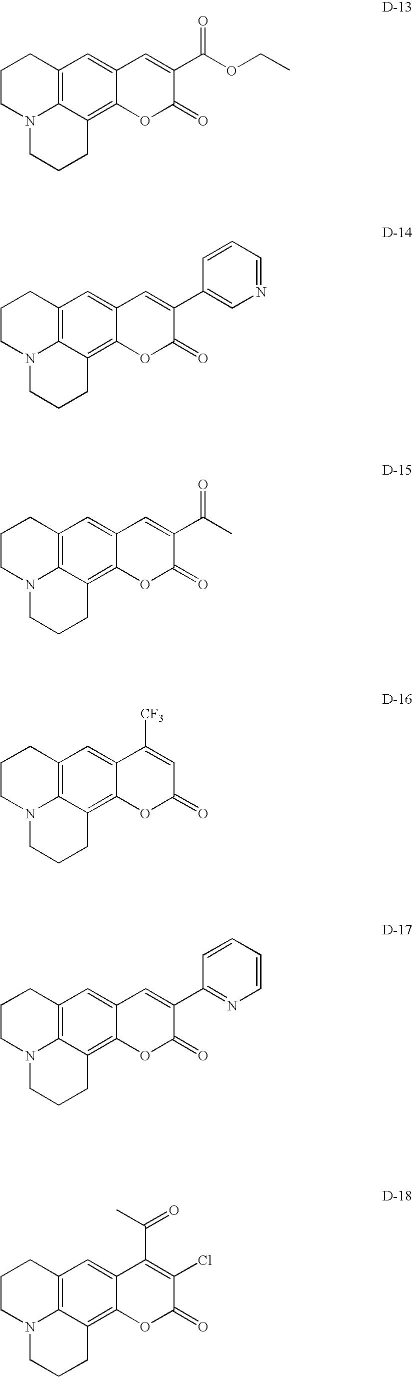

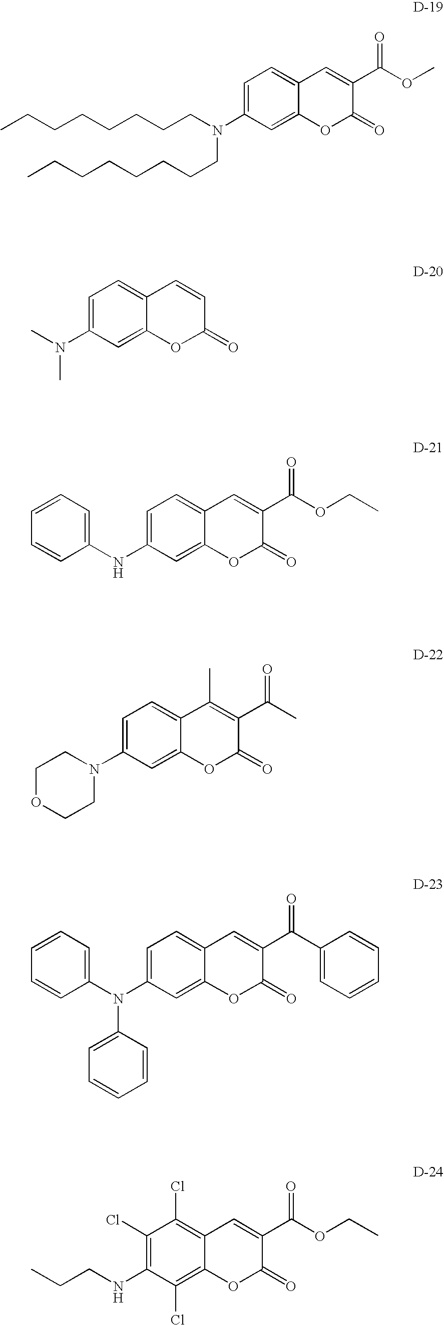

In addition to the foregoing examples, there are also preferably used coumalin derivatives of B-1 through B-22 described in JP-A H08-129258; coumalin derivatives of D-1 through D-32 described in JP-A 2003-21901; coumalin derivatives of 1 through 21 described in JP-A 2002-363206; coumalin derivatives of 1 through 40 described in JP-A 20.02-363207; coumalin derivatives of 1 through 34 described in JP-A 2002-363208; and coumalin derivatives of 1 through 56 described in JP-A 2002-363209.

Compound represented by the following formulae (E) and (F) are preferably employed as the stilbene derivative.

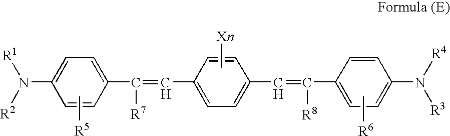

In the formula (E), R¹ through R⁴ represent, independently, a hydrogen atom, or an alkyl or aryl group which may have a substituent. R⁵ and R⁶ represent, independently, a hydrogen atom, a halogen atom, or an alkyl, aryl, alkoxy, or aryloxy group which may have a substituent. R⁷ and R⁸ represent, independently, a hydrogen atom, a halogen atom, a cyano group, or an alkyl group which may have a substituent. X is a halogen atom. n is an integer of 0-4.

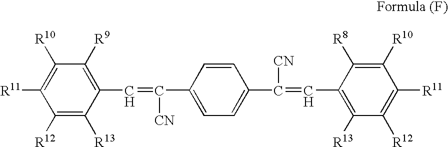

In the formula (F), R⁹ through R¹³ represent, independently, a hydrogen atom, a halogen atom, or an alkyl, alkoxy, aryl, aryloxy or alkyloxycarbonyl group which may have a substituent. R⁹ through R¹³ may form a ring by bonding each other.

Practical examples of compound represented by formula (E) and (F).

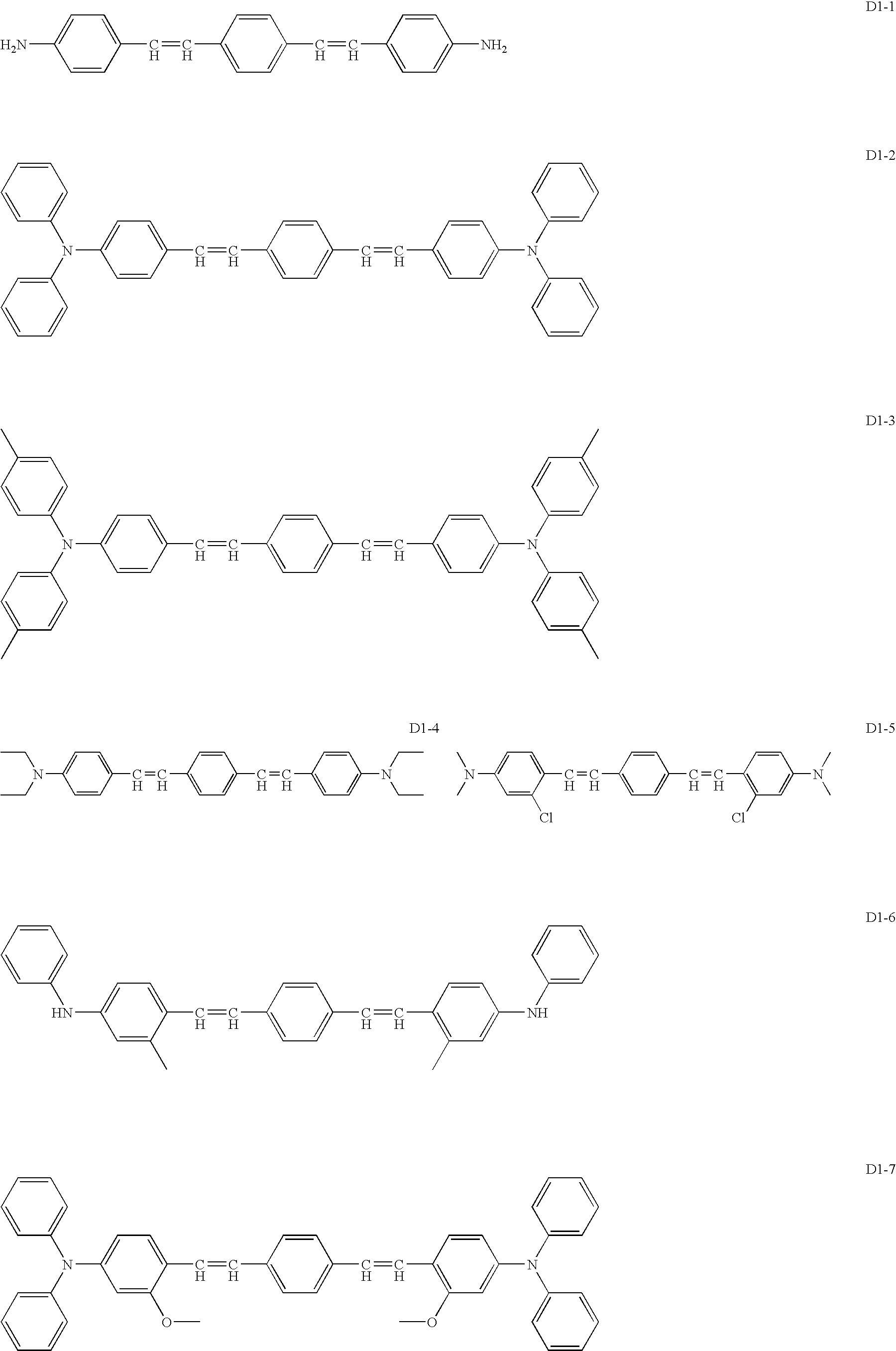

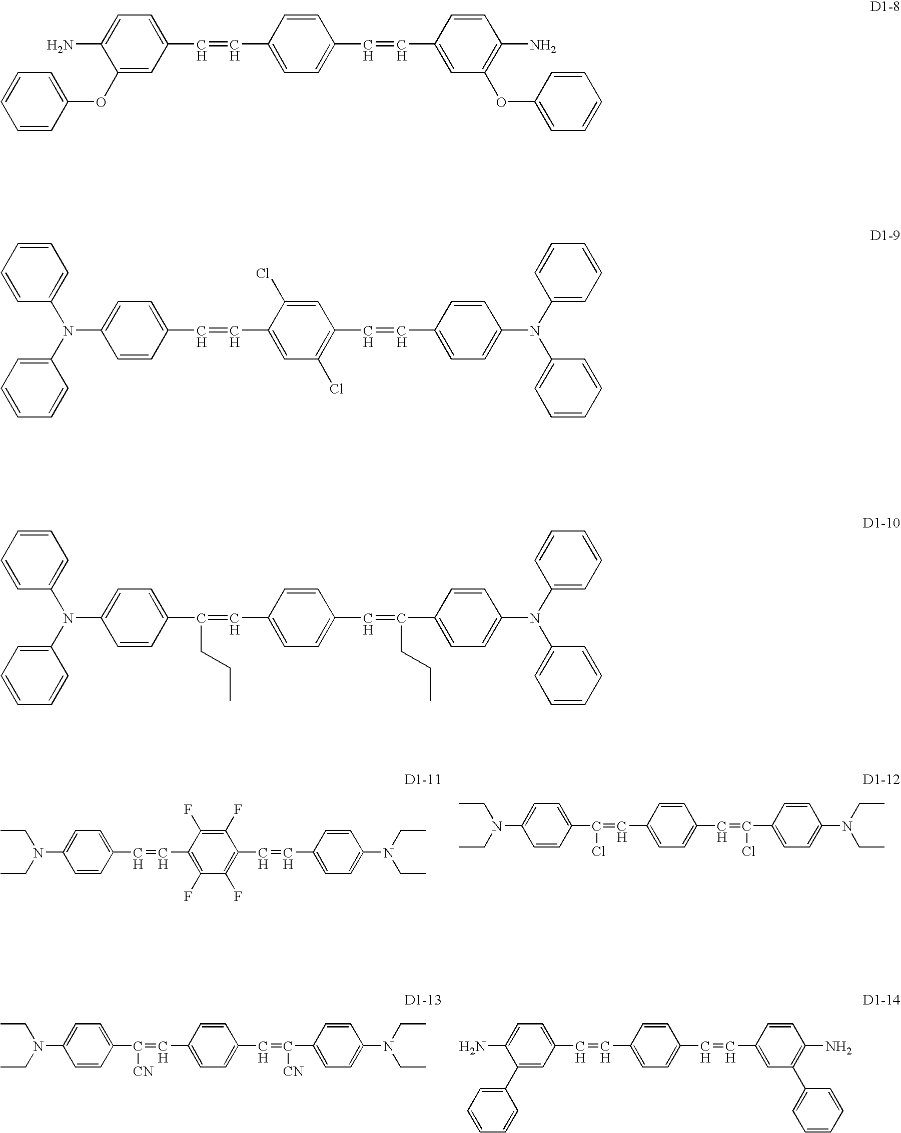

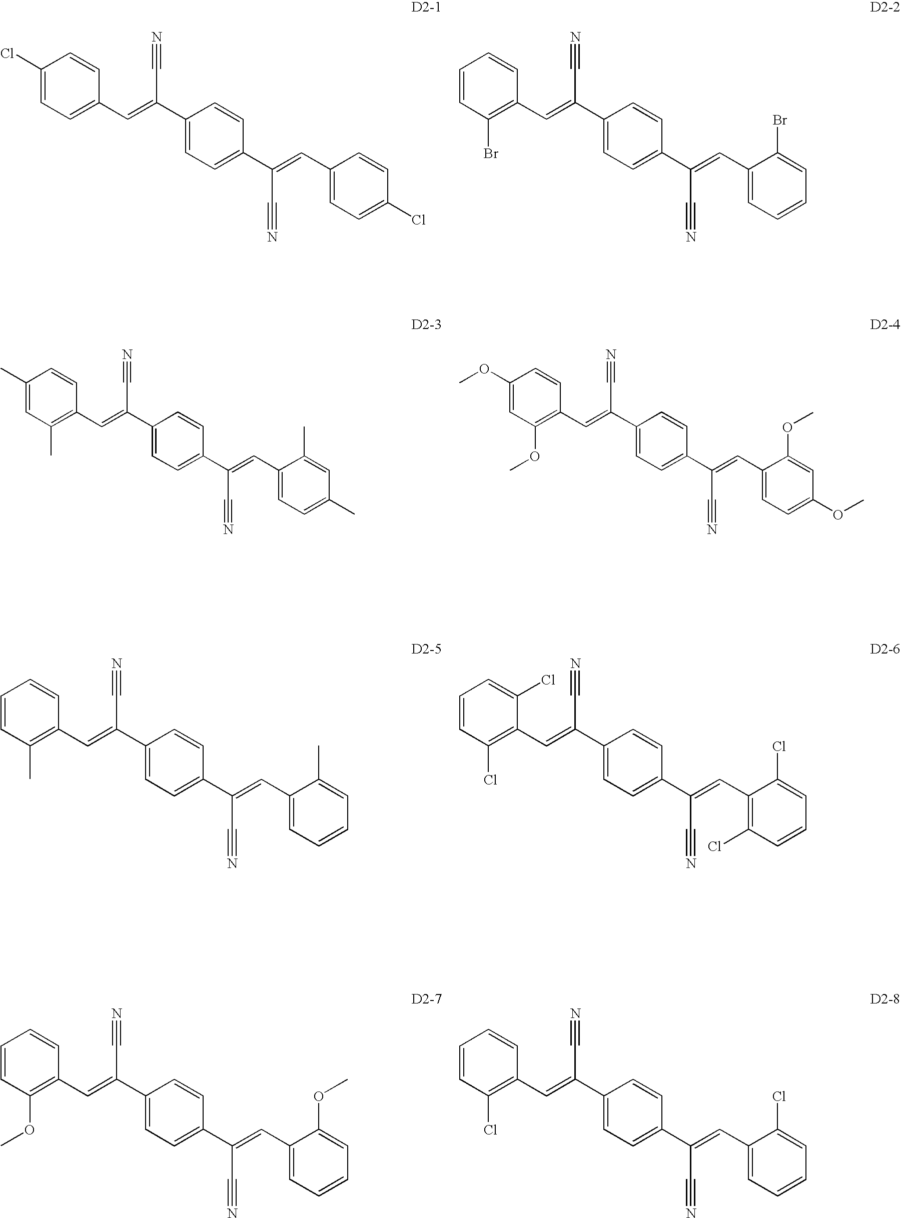

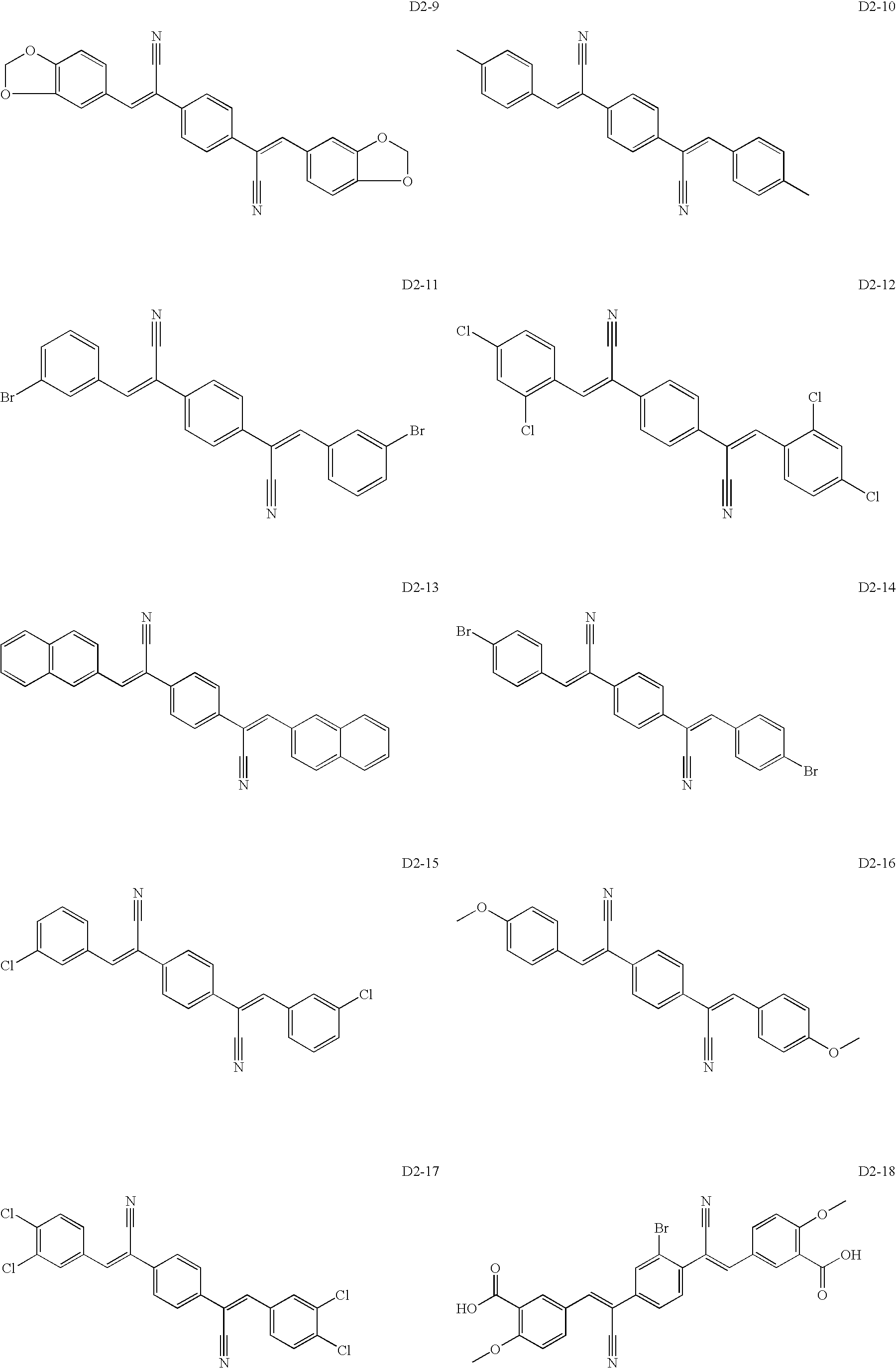

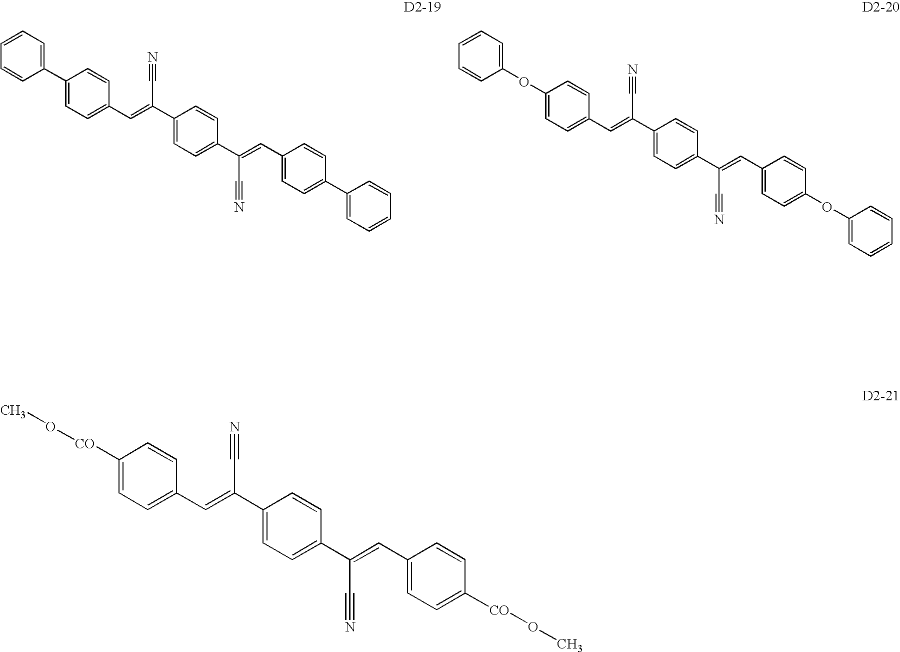

The following compound may be preferably used as a sensitizing dye.

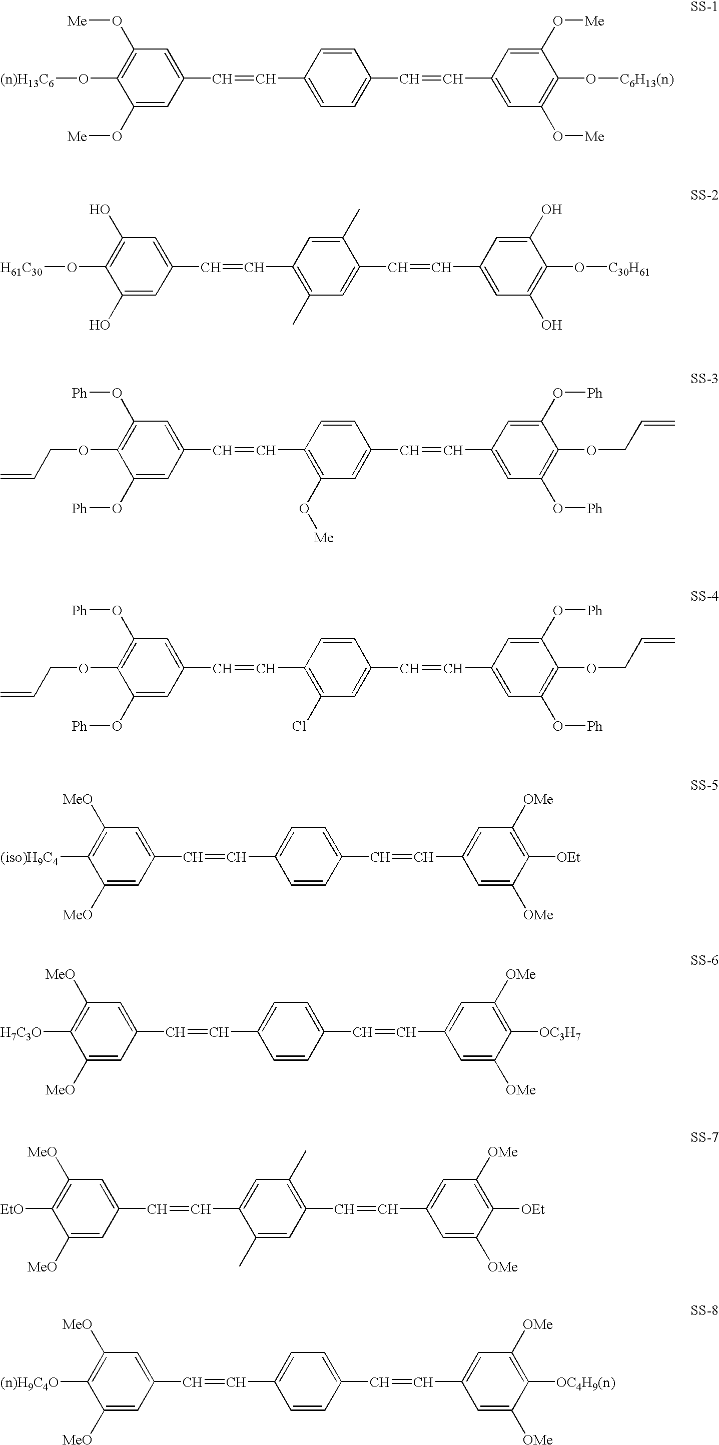

An amount of the sensitizing dye is preferably in the range of 0.5 to 10% by mass in terms of the photosensitive layer.

### Polymeric Binder Material

The polymeric binder material according to the invention is capable of carrying the components contained in the photosensitive layer. There are usable, as a polymeric binder material, an acrylic polymer, a polyvinylbutyral resin, polyurethane resin, polyamide resin, polyester resin, an epoxy resin, a phenol resin, a polycarbonate resin, polyvinyl butyral resin, polyvinyl formal resin, shellac and natural resins. These resins may be used in combination.

A vinyl copolymer obtained by copolymerization of vinyl monomers is preferred. A copolymer of (a) a carboxyl group-containing monomer and (b) an alkyl methacrylate or alkyl acrylate, as copolymerization composition of a polymeric binder material is more preferred.

Specific examples of a carboxyl group-containing monomer include α,β-unsaturated carboxylic acids such as acrylic acid, methacrylic acid, maleic acid, maleic acid anhydride, itaconic acid and itaconic acid anhydride. Further, a carboxylic acid such as a half ester of phthalic acid and 2-hydroxymethacrylate is also preferred.

Specific examples of an alkyl methacrylate and an alkyl acrylate include unsubstituted alkyl esters such as methyl methacrylate, ethyl methacrylate, propyl methacrylate, butyl methacrylate, amyl methacrylate, hexyl methacrylate, heptyl methacrylate, octyl methacrylate, nonyl methacrylate, decyl methacrylate, undecyl methacrylate, dodecyl methacrylate, methyl acrylate, ethyl acrylate, propyl acrylate, butyl acrylate, amyl acrylate; hexyl acrylate, heptyl acrylate, octyl acrylate, nonyl acrylate, decyl acrylate, undecyl acrylate and dodecyl acrylate; and in addition thereto cyclic alkyl esters such a cyclohexyl methacrylate and cyclohexyl acrylate; substituted alkyl esters such as 2-chloroethyl methacrylate, N,N-dimethylaminoethyl methacrylate, glycidyl methacrylate, benzyl acrylate, 2-chloroethyl acrylate, N,N-dimethylaminoethyl acrylate and glycidyl acrylate.

Further, a polymeric binder material can use, as a copolymerizable monomer, monomers (1) to (14), as described below.

(1) A monomer containing an aromatic hydroxyl group, for example, o-(or p- or m-)hydroxystyrene and o-(or p- or m-) hydroxyphenylacrylate.
(2) A monomer containing an aliphatic hydroxyl group, for example, 2-hydroxyethylacrylate, 2 hydroxyethylmethacrylate, N-methylolacrylamide, N-methylolmethacrylamide, 4-hydroxybutylmethacrylate, 5-hydroxypentylacrylate, 5-hydroxypentylmethacrylate, 6-hydroxyhexylacrylate, 6-hydroxyhexylmetacrylate, N-(2-hydroxyethyl)acrylamide, N-(2-hydroxyethyl)methacrylamide, and hydroxyethyl vinyl ether.
(3) A monomer containing an aminosulfonyl group, for example, m-(or p-)aminosulfonylphenyl methacrylate, m-(or p-) aminosulfonylphenyl acrylate, N (p-aminosulfonylphenyl)methacrylamide, and N-(p-aminosulfonylphenyl)acrylamide.
(4) A monomer containing a sulfonamido group, for example, N (p-toluenesulfonyl)acrylamide, and N-(p-toluenesulfonyl)methacrylamide.
(5) Acrylamides or methacrylamides, for example, acrylamide, methacrylamide, N-ethylacrylamide, N-hexylacrylamide, N-cyclohexylacrylamide, N-phenylacrylamide, N-(4-nitrophenyl)acrylamide, N-ethyl-N-phenylacrylamide, N-(4-hydroxyphenyl)acrylamide, and N-(4-hydroxyphenyl)methacrylamide.
(6) A monomer containing a fluoroalkyl group, for example, trifluoroethyl acrylate, trifluoroethyl methacrylate, tetrafluoropropyl methacrylate, hexafluoropropyl methacrylate, octafluoropentyl acrylate, octafluoropentyl methacrylate, heptadecafluorodecyl methacrylate, and N-butyl-N-(2-acryloxyethyl) heptadecafluorooctylsulfonamide.
(7) Vinyl ethers, for example, ethyl vinyl ether, 2-chloroethyl vinyl ether, propyl vinyl ether, butyl vinyl ether, octyl vinyl ether, and phenyl vinyl ether.
(8) Vinyl esters, for example, vinyl acetate, vinyl chloroacetate, vinyl butyrate, and vinyl benzoate.
(9) Styrenes, for example, styrene, methylstyrene, and chloromethylstyrene.
(10) Vinyl ketones, for example, methyl vinyl ketone, ethyl vinyl ketone, propyl vinyl ketone, and phenyl vinyl ketone.
(11) Olefins, for example, ethylene, propylene, i-butylene, butadiene, and isoprene.
(12) N-vinylpyrrolidone, N-vinylcarbazole, 4-vinylpyridine, and so on.
(13) A monomer containing a cyano group, for example, acrylonitrile, methacrylonitrile, 2-pentenenitrile, 2-methyl-3-butenenitrile, 2-cyanoethyl acrylate, and o-(or m- or p-) cyanostyrene.
(14) A monomer containing an amino group, for example, N,N-diethylaminoethyl methacrylate, N,N-dimethylaminoethyl acrylate, N,N-dimethylaminoethyl methacrylate, polybutadieneurethane acrylate, N,N-dimethylaminopropylacrylamidex N,N-dimethylacrylamide, acryloyl morpholine, N-1-propylacrylamide, and N,N-diethylacrylamide.

Further, other monomers which are copolymerizable with the foregoing monomers, may be copolymerized.

The polymeric binder material is preferably a vinyl type polymer having a carboxylic acid and a polymerizable double bond on a side chain. For example, an unsaturated bond-containing vinyl copolymer which is obtained by reacting a compound containing an acryloyl group and an epoxy group with the carboxyl group contained in the vinyl copolymer described above is preferred as a polymeric binder material. Specific examples of such a compound containing an acryloyl group and an epoxy group in the molecule include glycidyl acrylate, glycidyl methacrylate and an epoxy group-containing unsaturated compound described in JP-A No. 11-271969.

The vinyl polymer having a carboxyl group and a polymerizable double bond on a side chain is preferably 50-100% by mass, more preferably 100% by mass, of total polymer binder.

The content of a polymeric binder material contained in the photosensitive layer composition is preferably in the range of 10% to 90% by mass, more preferably 15% to 70% by mass, and still more preferably 20% to 50% by mass in view of sensitivity.

### Additives

The photosensitive layer according to this invention is preferably added with a polymerization inhibitor, in order to prevent undesired polymerization of the ethylenic unsaturated monomer during the manufacture or after storage of planographic printing plate material.

Examples of the polymerization inhibitor include hydroquinone, p-methoxyphenol, di-t-butyl-p-cresol, pyrogallol, t-butylcatechol, benzoquinone, 4,4′-thiobis(3-methyl-6-t-butylphenol), 2,2′-methylenebis (4-methyl-6-t-butylphenol), N-nitrosophenylhydroxylamine cerous salt, and 2-t-butyl-6-(3-t-butyl-2-hydroxy-5-methylbenzyl)-4-methylphenyl acrylate.

The addition amount of a polymerization inhibitor is preferably approximately 0.01%-5.0% based on the total solid weight of the aforesaid composition. Further, to prevent polymerization hindrance, added appropriately may be higher fatty acid derivatives such as behenic acid and behenic acid amide, which is localized on the surface of a photosensitive layer during the drying process after coating. The addition amount of a higher fatty acid derivative is preferably approximately 0.5-10.0% based on the total composition.

Further, a colorant can be also employed, and can be preferably utilized are commonly known colorants including those available on the market. For example, listed are those described in such as Pigment Hand Book, edited by Japan Pigment Technology Association (published by Seibundo Shinkosya) and Color Index Hand Book.

Types of pigments include a black pigment, a yellow pigment, a red pigment, a blown pigment, a purple pigment, a blue pigment, a green pigment, a fluorescent pigment and metallic powder pigment. Specifically, listed are inorganic pigments (such as titanium dioxide, carbon black, graphite, zinc oxide, Prussian Blue, cadmium sulfide, iron oxide and chromates of lead, zinc, barium and calcium), organic pigments (pigments of an azo type, a thioindigo type, an anthraquinone type, an anthanthrone type, a triphenedioxane type, a bat dye pigment, a phthalocyanine pigment and derivatives thereof, and quinacridone).

Among them, preferably utilized by appropriate selection is a pigment which essentially has no absorption in a wavelength region of a spectral sensitizing dye corresponding to an exposing laser employed; in this case, a reflective absorption of a pigment by means of an integrating cube with a laser wavelength utilized is preferably not more than 0.05. Further, an addition amount of a pigment is preferably 0.1-10.0 weight % and more preferably 0.2-5.0 weight %, based on the solid content of the aforesaid composition.

A purple pigment or a blue pigment are preferably utilized with respect to pigment absorption in the aforesaid photosensitive wavelength region and image visibility after development. Such pigments include, for example, Cobalt Blue, cerulean blue, Alkali Blue, Phonatone Blue 6G, Victoria Blue Lake, metal-free Phthalocyanine Blue, Phthalocyanine Fast Sky Blue, Indathrene Blue, indigo, Dioxane Violet, Isoviolanthrone Violet, Indanthrone Blue and Indanthrone BC. Among them, more preferable are Phthalocyanine Blue and Dioxane violet.

Further, the aforesaid composition can contain a surfactant as a coating aid in a range of not damaging characteristics of this invention. Among them preferable is a fluoride type surfactant.

Further, to improve physical properties of a cured film, added can be additives of such as an inorganic filling agent and a plasticizer such as dioctyl phthalate, dimethyl phthalate and tricresyl phosphate. An addition amount of these additives is preferably not more than 10% based on the total solid amount.

Further, solvents utilized to prepare a photosensitive composition of a photo-polymerizing photosensitive layer according to this invention preferably include, for example, alcohol and polyhydric alcohol derivatives such as sec-butanol, iso-butanol, n-hexanol, benzyl alcohol, diethylene glycol, triethylene glycol, tetraethylene glycol, 1,5-pentane diol; ether series such as propyleneglycol monobutylether, dipropyleneglycol monomethylether and tripropyleneglycol monomethylether; ketone series such as diacetone alcohol, cyclohexanone and methylcyclohexanone; aldehyde series; and ester series such as ethyl lactate, butyl lactate, diethyl oxalate and methyl benzoate.

The photosensitive layer according to this invention can be composed by coating the coating composition of the photosensitive layer as described above on a support.

The coverage of the photopolymerizable photosensitive layer containing constituents described above is preferably 0.1 to 10 g/m², and more preferably 0.5 to 5 g/m², based on the mass after being dried.

### Protective Layer (Oxygen Barrier Layer)

It is preferable to provide a protective barrier layer on the photosensitive layer according to this invention if necessary.

The protective layer (oxygen barrier layer) preferably has high solubility in a developing liquid (aqueous alkaline solution in general) described later. Specifically, polyvinyl alcohol or polyvinyl pyrrolidone is exemplified. Thus, polyvinyl alcohol is effective in inhibiting permeation of oxygen and polyvinyl pyrrolidone is effective in security of adhesion to an adjacent photosensitive layer. In addition to the foregoing two kinds of polymers, there may optionally be incorporated water-soluble polymers such as a polysaccharide, polyethylene glycol, gelatin, glue, casein, hydroxyethyl cellulose, carboxymethyl cellulose, methyl cellulose, hydroxyethyl starch, gum arabic, sucrose octaacetate, ammonium alginate, polyvinylamine, polyethylene oxide, polystyrensulfonic acid, polyacrylic acid, and water-soluble polyamide.

The planographic printing plate material according to this invention preferably exhibits a peeling power between the photosensitive layer and the protective layer of not less than 35 mN/mm, more preferably not less than 50 mN/mm, and still more preferably not less than 75 mN/mm. A preferred composition of the protective layer is disclosed in, for example, JP-Application H08-161645.

The peeling power can be determined, for instance, in such a manner that a given wide adhesive tape exhibiting sufficient adhesion power is adhered to the protective layer and peeled off together with the protective layer at an angle of 90° to the surface of the printing plate material to determine the power necessary for peeling-off.

The overcoat may optionally contain a surfactant and a matting agent. The composition of a protective layer, as described above is dissolved in an appropriate solvent, coated on the photosensitive layer and dried to form a protective layer. The main component of such a solvent is preferably water or alcohols such as methanol, ethanol or i-propanol.

The thickness of a protective layer is preferably 0.1-5.0 μm, and particularly preferably 0.5-3.0 μm.

### Support

The support used in the invention is a plate or a sheet capable of carrying the photosensitive layer and preferably has a hydrophilic surface on the side on which the photosensitive layer is to be provided.

As the supports used in the invention, a plate of a metal such as aluminum, stainless steel, chromium or nickel, or a plastic film such as a polyester film, a polyethylene film or a polypropylene film, which is deposited or laminated with the above-described metal can be used.

Further, a polyester film, a polyvinyl chloride film or a nylon film whose surface is subjected to hydrophilization treatment can be used.

Among the above, the aluminum plate is preferably used, and may be a pure aluminum plate or an aluminum alloy plate.

As the aluminum alloy, there can be used various ones including an alloy of aluminum and a metal such as silicon, copper, manganese, magnesium, chromium, zinc, lead, bismuth, nickel, titanium, sodium or iron. In the aluminum plate for the support, the surface is roughened for water retention.

It is preferable that the support in the invention is subjected to degreasing treatment for removing rolling oil prior to surface roughening (graining). The degreasing treatments include degreasing treatment employing solvents such as trichlene and thinner, and an emulsion degreasing treatment employing an emulsion such as kerosene or triethanol. It is also possible to use an aqueous alkali solution such as caustic soda for the degreasing treatment. When an aqueous alkali solution such as caustic soda is used for the degreasing treatment, it is possible to remove soils and an oxidized film which can not be removed by the above-mentioned degreasing treatment alone. When an aqueous alkali solution such as caustic soda is used for the degreasing treatment, the resulting support is preferably subjected to de-smut treatment in an aqueous solution of an acid such as phosphoric acid, nitric acid, sulfuric acid, chromic acid, or a mixture thereof, since smut is produced on the surface of the support. The surface roughening methods include a mechanical surface roughening method and an electrolytic surface roughening method electrolytically etching the support surface.

Though there is no restriction for the mechanical surface roughening method, a brushing roughening method and a honing roughening method are preferable.

Though there is no restriction for the electrolytic surface roughening method, a method, in which the support is electrolytically surface roughened in an acidic electrolytic solution, is preferred.

After the support has been electrolytically surface roughened, it is preferably dipped in an acid or an aqueous alkali solution in order to remove aluminum dust, etc. produced in the surface of the support. Examples of the acid include sulfuric acid, persulfuric acid, hydrofluoric acid, phosphoric acid, nitric acid and hydrochloric acid, and examples of the alkali include sodium hydroxide and potassium hydroxide. Among those mentioned above, the aqueous alkali solution is preferably used.

The dissolution amount of aluminum in the support surface is preferably 0.5 to 5 g/m². After the support has been dipped in the aqueous alkali solution, it is preferable for the support to be dipped in an acid such as phosphoric acid, nitric acid, sulfuric acid and chromic acid, or in a mixed acid thereof, for neutralization.

The mechanical surface roughening and electrolytic surface roughening may be carried out singly, and the mechanical surface roughening followed by the electrolytic surface roughening may be carried out.

After the surface roughening, anodizing treatment may be carried out. There is no restriction in particular for the method of anodizing treatment used in the invention, and known methods can be used. The anodizing treatment forms an oxide film on the surface of the support.

The support, which has been subjected to anodizing treatment, is optionally subjected to sealing treatment. For the sealing treatment, it is possible to use known methods using hot water, boiling water, steam, a sodium silicate solution, an aqueous dichromate solution, a nitrite solution and an ammonium acetate solution.

After the above treatment, the support is suitably undercoated with a water soluble resin such as polyvinyl phosphonic acid, a polymer or copolymer having a sulfonic acid in the side chain, or polyacrylic acid; a water soluble metal salt such as zinc borate; a yellow dye; an amine salt; and so on, for hydrophilization treatment. The sol-gel treatment support disclosed in JP-A H05-304358, which has a functional group capable of causing addition reaction by radicals as a covalent bond, is suitably used.

### Coating

The photosensitive layer is formed by preparing a coating liquid for the photosensitive layer and coating the liquid on the support according to a coating conventional method, and drying, whereby a planographic printing plate material is obtained.

Examples of the coating method include an air doctor coating method, a blade coating method, a wire bar coating method, a knife coating method, a dip coating method, a reverse roll coating method, a gravure coating method, a cast coating method, a curtain coating method, and an extrusion coating method.

A drying temperature of the coated photosensitive layer is preferably from 60 to 160° C., more preferably from 80 to 140° C., and still more preferably from 90 to 120° C., in view of fog occurrence at non-image portions.

### Image Exposure

As light sources for forming an image on the planographic printing plate material in the invention, laser having an emission wavelength of 370-440 nm is preferably used.

Listed examples of lasers are, He—Cd laser (441 nm); a combination of solid laser Cr:LiSAF and SHG crystal (430 nm); semiconductor laser KNbO₃; ring resonator (430 nm); AlGaInN (350 450 nm); AlGaInN semiconductor laser (InGaN series semiconductor laser on the market, 400-410 nm) for the planographic printing material of this invention.

When a laser is used for exposure, which can be condensed in the beam form, scanning exposure according to an image can be carried out, and direct writing is possible without using any mask material.

When the laser is employed for imagewise exposure, a high dissolution image can be obtained, since it is easy to condense its exposure spot in minute size.

As a laser scanning method by means of a laser beam, there are a method of scanning on an outer surface of a cylinder, a method of scanning on an inner surface of a cylinder and a method of scanning on a plane. In the method of scanning on an outer surface of a cylinder, laser beam exposure is conducted while a drum around which a recording material is wound is rotated, in which main scanning is represented by the rotation of the drum, while sub-scanning is represented by the movement of the laser beam. In the method of scanning on an inner surface of a cylinder, a recording material is fixed on the inner surface of a drum, a laser beam is emitted from the inside, and main scanning is carried out in the circumferential direction by rotating a part of or an entire part of an optical system, while sub-scanning is carried out in the axial direction by moving straight a part of or an entire part of the optical system in parallel with a shaft of the drum. In the method of scanning on a plane, main scanning by means of a laser beam is carried out through a combination of a polygon mirror, a galvano mirror and an Fθ lens, and sub-scanning is carried out by moving a recording medium.

Imagewise exposure is carried out at a plate surface energy (exposure energy at the surface of the planographic printing plate material) of from 10 to 500 mJ/cm², and more preferably from 10 to 300 mJ/cm² in the invention. This exposure energy can be measured, employing a laser power meter PDGDO-3W produced by Ophir Optronics Inc.

### Developer

The imagewise exposed photosensitive layer, which are cured at exposed portions, is developed with an alkali developer, whereby the photosensitive layer at unexposed portions is removed to form an image.

As the alkali developer, a conventional alkali aqueous solution is used. For example, there is an alkali developer containing an inorganic alkali agent such as sodium silicate, potassium silicate, ammonium silicate; sodium secondary phosphate, potassium secondary phosphate, ammonium secondary phosphate; sodium hydrogen carbonate, potassium hydrogen carbonate, ammonium hydrogen carbonate; sodium carbonate, potassium carbonate, ammonium carbonate; sodium borate, potassium borate, lithium borate; sodium hydroxide, potassium hydroxide, and ammonium hydroxide.

The alkali developer can contain organic alkali agents such as monomethylamine, dimethylamine, trimethylamine, monoethylamine, diethylamine, triethylamine, mono-i-propylamrine, di-i-propylamine, tri-i-propylamine, butylamine, monoethanolamine, diethanolamine, triethanolamine, mono-i-propanolamine, di-i-propanolamine, ethyleneimine, ethylenediamine, and pyridine.

These alkali agents can be used singly or as a mixture of two or more thereof. The alkali developer can contain an anionic surfactant, an amphoteric surfactant, or an organic solvent such as alcohol.

The alkali developer can be prepared from a developing composition in the form of tablets or granules or a developer concentrate.

The developer concentrate may be prepared by forming a developer solution, followed by evaporation to dryness and is preferably prepared in such a manner that plural components are mixed with a small amount of water or without adding any water. The developer concentrate can also be prepared in the form of granules or tablets, as described in JP-A S51-61837, H02-109042, H02-109043, H03-39735, H05-142786, H06-266062 and H07-13341. The developer concentrate may be divided into plural parts differing in material species or compounding ratio.

The developer or developer replenisher in the invention can further contain an antiseptic agent, a coloring agent, a thickening agent, an antifoaming agent, or a water softener.

### Automatic Developing Machine

It is advantageous that an automatic developing machine is used in order to develop a photosensitive planographic printing plate material. It is preferred that the automatic developing machine is equipped with a means for automatically introducing a developer replenisher in a necessary amount into a developing bath, a means for discharging any excessive developer and a means for automatically introducing water in necessary amounts to the developing bath. It is preferred that the automatic developing machine comprises a means for detecting a planographic printing plate material to be transported, a means for calculating the area to be processed of the planographic printing plate material based on the detection, or a means for controlling a replenishing amount of a developer replenisher, a replenishing amount of water to be replenished or replenishing timing based on the detection and calculation. It is also preferred that the automatic developing machine comprises a means for controlling a temperature of a developer, a means for detecting a pH and/or electric conductivity of a developer, or a means for controlling a replenishing amount of the developer replenisher, a replenishing amount of water to be replenished and/or the replenishing timing based on the detected pH and/or electric conductivity. It is also preferred that the automatic developing machine have a function of diluting a developer concentrate with water and a function of stirring the diluted concentrate. Where developing is followed by washing, water used for washing can be reused as a dilution water for diluting the developer concentrate.

The automatic developing machine used in the invention may be provided with a pre-processing section to allow the plate to be immersed in a preprocessing solution prior to development. The pre-processing section is provided preferably with a mechanism of spraying a pre-processing solution onto the plate surface, preferably with a mechanism of controlling the pre-processing solution at a temperature within the range of 25 to 55° C., and preferably with a mechanism of rubbing the plate surface with a roller-type brush. Common water and the like are employed as the pre-processing solution.

### Post-Processing

The developed printing plate-material is preferably subjected to post-processing. The post-processing step comprises post-processing the developed precursor with a post-processing solution such as washing water, a rinsing solution containing a surfactant, a finisher or a protective gumming solution containing gum arabic or starch derivatives as a main component. The post-processing step is carried out employing an appropriate combination of the post-processing solution described above. For example, a method is preferred in which a developed planographic printing plate precursor is post-washed with washing water, and then processed with a rinsing solution containing a surfactant, or a developed planographic printing plate precursor is post-washed with washing water, and then processed with a finisher, since it reduces fatigue of the rinsing solution or the finisher. It is preferred that a multi-step countercurrent processing is carried out employing a rinsing solution or a finisher.

The post-processing is carried out employing an automatic developing machine having a development section and a post-processing section. In the post-processing step, the developed printing plate is sprayed with the post-processing solution from a spray nozzle or is immersed into the post-processing solution in a post-processing tank. A method is known in which supplies a small amount of water onto the developed printing plate precursor to wash the precursor, and reuses the water used for washing as dilution water for developer concentrate. In the automatic developing machine, a method is applied in which each processing solution is replenished with the respective processing replenisher according to the area of the printing plate precursor to have been processed or the operating time of the machine. A use-and-discard method can be applied in which the developed printing plate material is processed with fresh processing solution and discarded. The thus obtained planographic printing plate is mounted on an off-set printing press, and printing is carried out.

### EXAMPLES

The present invention will be further described with reference to examples but embodiments of the invention are by no means limited to these. In the following examples, unless otherwise noted, “part(s)” and “%” represent part(s) by mass and % by mass, respectively.

### Preparation of Support

A 0.3 mm thick aluminum plate (material: 1050, thermal refining: H16) was immersed into an aqueous 51 sodium hydroxide solution maintained at 65° C., then subjected to a degreasing treatment for 1 min. and subsequently washed. The thus degreased aluminum plate was then immersed in an aqueous 10% hydrochloric acid solution maintained at 25° C. for 1 min. to allow neutralization and then washed.

Subsequently, the aluminum plate was treated in an aqueous 0.3% nitric acid solution at 25° C. for 60 sec. by an alternating current at a current density of 100 A/dm² to perform electrolytic surface-roughening and then subjected to a de-smutting treatment in an aqueous 5% sodium hydroxide solution maintained at 60° C. for 10 sec.

The surface-roughened aluminum plate was subjected to an anodic oxidation treatment in a 15% sulfuric acid solution at 25° C. for 1 min. under conditions of a current density of 10 A/dm² and a voltage of 15 V and further subjected to a hydrophilization treatment in 1% poly(vinylphosphonic acid) at 75° C. to obtain a support.

The surface of the support exhibited a center-line mean roughness (Ra) of 0.65 μm.

### Preparation of Printing Plate Material

A coating solution of a photopolymerizable photosensitive layer of the following composition was coated by a wire-bar on the foregoing support so as to have a dry coverage of 1.5 g/m² and dried at 95° C. for 1.5 min., then a coating solution of an oxygen barrier layer of the following composition was coated by an applicator so as to have a dry coverage of 1.5 g/m² and then dried at 75° C. for 1.5 min. to prepare a planographic printing plate material of inventive samples 1-12 and comparative samples 1-3.

### Coating Composition for Photosensitive Layer

| | |
|---|---|
| Reaction product according to this invention shown in | 42.0 parts |
| Table 1 (50% DAWANOL PMA, propylene glycol | |
| methylethylacetate, produced by Dow Corp.) | |
| Triethyleneglycol dimethacrylate | 6.0 parts |
| Copolymer of methacrylic acid and methacrylate | 35.0 parts |
| (mass ratio: 25/75, Molecular weight of 36,000) | |
| Spectral Sensitizing Dye | 4.0 parts |
| (as shown in Table 1) | |
| 2,2′-bis(2-chlorophenyl)-4,5,4′,5′- | 3.0 parts |
| tetraphenylbiimidazole | |
| 2-Mercaptobenzothiazole | 0.3 parts |
| N-phenylglycine benzyl ester | 4.0 parts |
| Phthalocyanine pigment (MHI 454, produced by | 3.5 parts |
| Mikuni Color Ltd.) | |
| 2-t-butyl-6-(3-t-butyl-2-hydroxy-5- | 0.2 parts |
| methylbezyl)-4-methylphenylacrylate | |
| (SUMILIZER GS, produced by Sumitomo 3M) | |
| 2,4,6-tris(dimethylaminomethyl)phenol | 1.0 parts |
| Bis(2,2,6,6-tetramethyl-4-piperydyl)sebacate | 0.1 parts |
| Fluorine-contained surfactant (F-178K, produced | 0.5 parts |
| by DIC Corp.,) | |
| Siloxane surfactant (BYK 337, produced by BYK- | 0.9 parts |
| Chemie GmbH) | |
| Methyl ethyl ketone | 80 parts |
| Propylene glycol methylether | 820 parts |

### (Oxygen Barrier Layer Coating Composition)

| | |
|---|---|
| Polyvinyl alcohol (CELVOL 103, produced by | 85.0 parts |
| Celanese Corp.) | |
| Polyvinyl Pyrrolidone (PVP LUVITEC VA64W, | 15.0 parts |
| produced by BASF Co., Ltd.) | |
| SURFYNOL 465 (produced by Air Products and | 0.2 parts |
| Chemicals, Inc. | |
| Water | 900 parts |

### Evaluation of Photosensitive Planographic Printing Plate Material

### (Sensitivity)

Employing a plate setter (ECRM News CTP) installed with a 60 mW light source emitting a 405 nm light, the photosensitive planographic printing plate material obtained above was imagewise exposed at a resolving degree of 2400 dpi. Herein, dpi represents the dot numbers per 2.54 cm.

The image pattern used for the exposure comprised a 100% solid image, and a copy image data having hollow characters of capital and small alphabetic letters with 3-10 points Times New Roman font.

Subsequently, the exposed sample was subjected to development treatment employing a CTP automatic developing machine (Raptor Polymer produced by Glunz & Jensen Inc.) to obtain a planographic printing plate. Herein, the developing machine comprised a preheating section set at 105° C., a pre-washing section for removing the oxygen shielding layer before development, a development section set at 30° C. and charged with developer having the following developer composition, a washing section for removing the developer remaining on the developed sample after development, and a gumming section charged with a gumming solution (a solution obtained by diluting GW-3, produced by Mitsubishi Chemical Corp., with water by a factor of 2) for protecting the surface of the developed sample. Thus, planographic printing plate was obtained.

### Developer Composition (Aqueous Solution Containing the Following Components)

| | |
|---|---|
| Potassium silicate A | 8.0 parts |
| Surfactant Newcol B-13SN (produced by | 3.0 parts |
| Nippon Nyukazai Co., Ltd.) | |
| Water | 89.0 parts |
| Potassium hydroxide | amount giving |
| | pH 12.3 |

The minimum exposure energy, at which no thickness reduction of the solid image layer having 100 image area of the resulting printing plate obtained was observed, was defined as recording energy and evaluated as a measure of sensitivity. The less the recording energy is, the higher the sensitivity.

(Sensitivity Change after Storage)

The printing plate material sample obtained above was packed in a light-shielding package and stored at 55° C. for three days in a thermostat. Sensitivity change comparing with that of before storage of the resulting sample was determined in percent.

It is demonstrated that the closer to 100% is the value, the better the storage is.

The results are shown in Table 1. As apparent from the Table, the planographic printing plates of this invention is excellent in sensitivity and storage properties.

TABLE 1

| | Polymer Compound | | | | | Sensitivity |
|---|---|---|---|---|---|---|
| | Reaction product of | | | Sensitizing | | Change after |
| Sample | (a) | (b) | (c) | Dye | Sensitivity | Storage |
| Example 1 | AA1 | N18 | HEMA | D-1 | 15 μJ/cm² | 110% |
| | (1 mol) | (2 mol) | (2 mol) | | | |
| Example 2 | AA8 | N21 | HEMA | D-1 | 20 μJ/cm² | 110% |
| | (1 mol) | (2 mol) | (2 mol) | | | |
| Example 3 | AA2 | N09 | HEMA | D-1 | 20 μJ/cm² | 120% |
| | (1 mol) | (2 mol) | (2 mol) | | | |
| Example 4 | AA6 | N12 | HEMA | D-2 | 15 μJ/cm² | 130% |
| | (1 mol) | (2 mol) | (2 mol) | | | |
| Example 5 | AA7 | N16 | HEA | D-2 | 20 μJ/cm² | 120% |
| | (1 mol) | (2 mol) | (2 mol) | | | |
| Comparative | PG | N18 | HEMA | D-1 | 80 μJ/cm² | No image |
| Sample 1 | (1 mol) | (2 mol) | (2 mol) | | | was |
| | | | | | | formed. |
| Comparative | EP | N18 | HEMA | D-2 | 45 μJ/cm² | 170% |
| Sample 2 | (1 mol) | (2 mol) | (2 mol) | | | |

HEMA: 2-Hydroxyethyl methacrylate
HEA: 2-Hydroxyethyl acrylate
PG: Propylene glycol
EP: 2-(2-hydroxyethyl)piperidine
D-1: 1,4-bis(4-isobutoxy-3,5-dimethoxystyryl)benzene
D-2: 7-diethylamino-3-ethoxycarbocoumarine

1. A photosensitive planographic printing plate material having a photosensitive layer comprising (A) a polymerization initiator, (B) a polymerizable compound having ethylenic double bond, (C) a sensitizing dye, and (D) a polymer binder,
on a support,
wherein the polymerizable compound having ethylenic double bond is a reaction product of (a) a compound represented by Formula (1), (b) a diisocyanate compound, and (c) a methacrylate or acrylate compound having a hydroxy group in a molecule.
HO—(CH₂)ₙ—NH—CHR¹R² Formula (1)
in the formula, R¹ and R² independently represent an alkyl or aralkyl group, R¹ and R² may form a ring by bonding, and n is an integer of 1-10.

2. A photosensitive planographic printing plate material of claim 1, wherein (A) a polymerization initiator is a hexarylbiimidazole compound.

3. A photosensitive planographic printing plate material of claim 1, wherein (C) a sensitizing dye is a coumarin derivative or a stilbene derivative.
